(19) United States
(12) Patent Application Publication
(10) Pub. No.: US 2025/0194084 A1
(43) Pub. Date: Jun. 12, 2025

(54) SEMICONDUCTOR DEVICE AND METHOD OF MANUFACTURING THE SAME

(71) Applicant: SAMSUNG ELECTRONICS CO., LTD., SUWON-SI (KR)

(72) Inventors: Seokjun Hong, Suwon-si (KR); Donghoon Kwon, Suwon-si (KR); Sohyeon Park, Suwon-si (KR); Yanghee Lee, Suwon-si (KR)

(21) Appl. No.: 18/971,593

(22) Filed: Dec. 6, 2024

(30) Foreign Application Priority Data
Dec. 12, 2023 (KR) 10-2023-0180098

(51) Int. Cl. H10B 12/00

(52) U.S. Cl. CPC H10B 12/50; H10B 12/09; H10B 12/315

(57) ABSTRACT

A semiconductor device includes a substrate including a memory cell region and a peripheral circuit region, the memory cell region having a first active region and the peripheral circuit region having a second active region, a capacitor structure formed in the memory cell region and including a lower electrode connected to the first active region, an upper electrode surrounding the lower electrode, and a capacitor dielectric film disposed therebetween, a lower insulating film disposed in the memory cell region and the peripheral circuit region and covering the capacitor structure, a first interlayer insulating film including a first lower interlayer insulating film and a first upper interlayer insulating film sequentially stacked on the lower insulating film, and a wiring line disposed in the first interlayer insulating film and electrically connected to the capacitor structure, in which the first upper interlayer insulating film includes a first material including a benzene ring.

### CROSS-REFERENCE TO RELATED APPLICATION

This application claims priority under 35 U.S.C. § 119 to Korean Patent Application No. 10-2023-0180098, filed on Dec. 12, 2023, in the Korean Intellectual Property Office, the disclosure of which is incorporated by reference herein in its entirety.

### TECHNICAL FIELD

The present inventive concept relates to a semiconductor device and a method of manufacturing the same, and more particularly, to a semiconductor device including a metal wiring and a method of manufacturing the same.

### DISCUSSION OF RELATED ART

Semiconductor devices have become more compact and lightweight through a rapid progress in down-scaling and high integration, in accordance with the development of the electronics industry and user demands. As the high integration of the semiconductor devices is continuously increasing and the size of the semiconductor devices is significantly reduced accordingly, the reliability of the semiconductor devices may decrease. However, to meet the ever-increasing demand for semiconductor devices to have high performance and high reliability by the electronics industry, much research has been conducted to enhance the reliability of the semiconductor devices.

### SUMMARY

The present inventive concept provides a semiconductor device with enhanced electrical characteristics and reliability, and a method of manufacturing the same.

According to an embodiment of the present inventive concept, there is provided a semiconductor device including a substrate including a memory cell region and a peripheral circuit region, the memory cell region having a first active region and the peripheral circuit region having a second active region, a capacitor structure including a lower electrode connected to the first active region in the memory cell region, an upper electrode surrounding the lower electrode in the memory cell region, and a capacitor dielectric film disposed between the lower electrode and the upper electrode, a lower insulating film disposed on the substrate in the memory cell region and the peripheral circuit region, and covering the capacitor structure in the memory cell region, a first interlayer insulating film including a first lower interlayer insulating film and a first upper interlayer insulating film sequentially stacked on the lower insulating film, and a wiring line disposed in the first interlayer insulating film and electrically connected to the capacitor structure, in which the first upper interlayer insulating film includes a first material including a benzene ring.

According to an embodiment of the present inventive concept, there is provided a method of manufacturing a semiconductor device, the method including providing a substrate including a memory cell region and a peripheral circuit region, the memory cell region having a first active region and the peripheral circuit region having a second active region, forming a capacitor structure connected to the first active region in the memory cell region, forming a lower insulating film covering the substrate and the capacitor structure, forming a plurality of cell contacts penetrating the lower insulating film in the memory cell region and forming peripheral circuit contacts penetrating the lower insulating film on the peripheral circuit region, forming a first interlayer insulating film including a first lower interlayer insulating film and a first upper interlayer insulating film sequentially stacked on the lower insulating film, and forming a wiring line disposed in the first interlayer insulating film and electrically connected to the capacitor structure, in which the first upper interlayer insulating film includes a first material including a benzene ring.

According to an embodiment of the present inventive concept, there is provided a semiconductor device including a substrate including a memory cell region and a peripheral circuit region, the memory cell region having a first active region and the peripheral circuit region having a second active region, a capacitor structure including a lower electrode connected to the first active region in the memory cell region, an upper electrode surrounding the lower electrode in the memory cell region, and a capacitor dielectric film disposed between the lower electrode and the upper electrode, a lower insulating film disposed on the substrate in the memory cell region and the peripheral circuit region, and covering the capacitor structure in the memory cell region, a first interlayer insulating film disposed on the lower insulating film and including a first upper interlayer insulating film including a first material including a benzene ring and a first lower interlayer insulating film including a low dielectric material of a same type as the first material; and a wiring line disposed in the first interlayer insulating film and electrically connected to the capacitor structure, and including sidewalls that are coplanar in a region adjacent to a boundary where the first lower interlayer insulating film and the first upper interlayer insulating film are in contact with each other, wherein the first upper interlayer insulating film is represented by the following Chemical Formula 1:

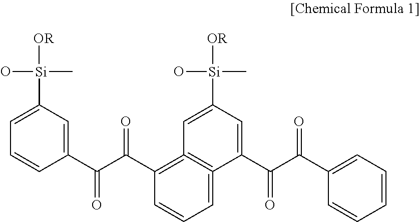

in Chemical Formula 1, R represents an alkyl group, and O—Si— represents Chemical Formula 1 being repeatedly linked to Chemical Formula 1 through SiO bond.

### BRIEF DESCRIPTION OF THE DRAWINGS

Embodiments of the present inventive concept will be more clearly understood from the following detailed description taken in conjunction with the accompanying drawings in which:

FIG. 1 is a layout diagram showing a semiconductor device according to an embodiment of the present inventive concept;

FIG. 2 is an enlarged view of part EX1 of FIG. 1;

FIG. 3 is a cross-sectional view taken along line A-A′ in FIG. 2;

FIGS. 4 to 14 are cross-sectional views for explaining a method of manufacturing a semiconductor device according to an embodiment of the present inventive concept; and

FIG. 15 is a cross-sectional view of a semiconductor device taken along line A-A′ of FIG. 2 according to an embodiment of the present inventive concept.

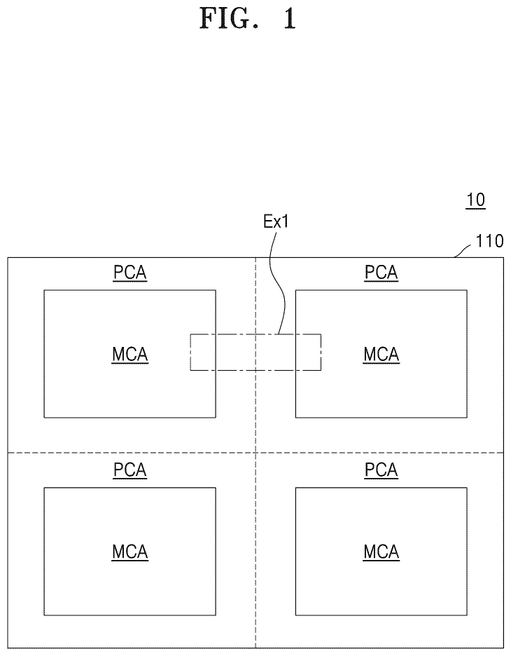

Since the drawings in FIGS. 1-15 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, embodiments of the present inventive concept will be described in detail with reference to the accompanying drawings. Like reference numerals are used for like elements in the drawings, and the descriptions thereof are omitted.

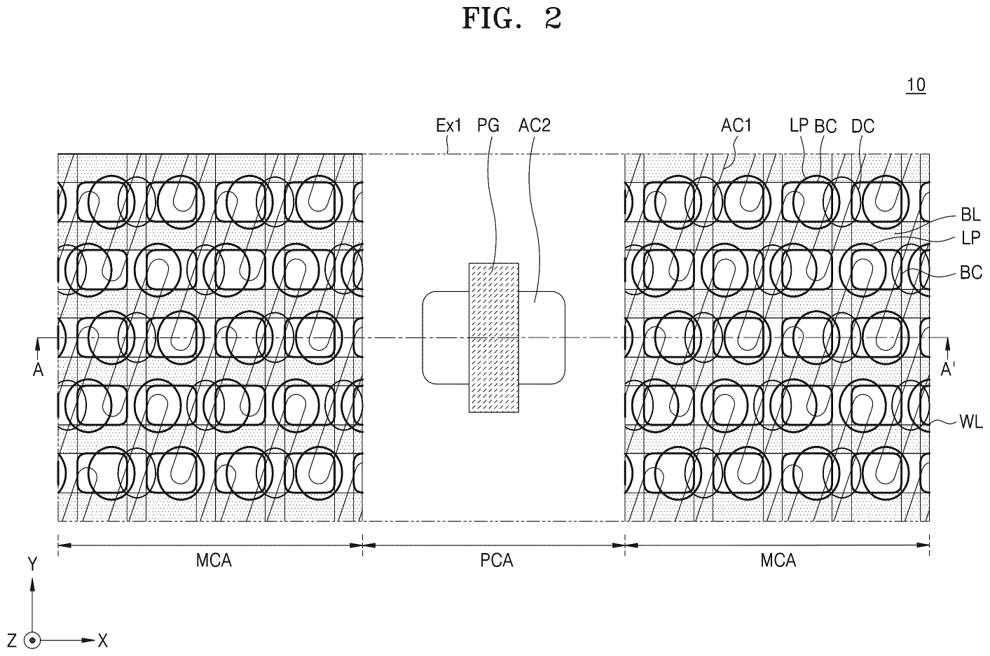

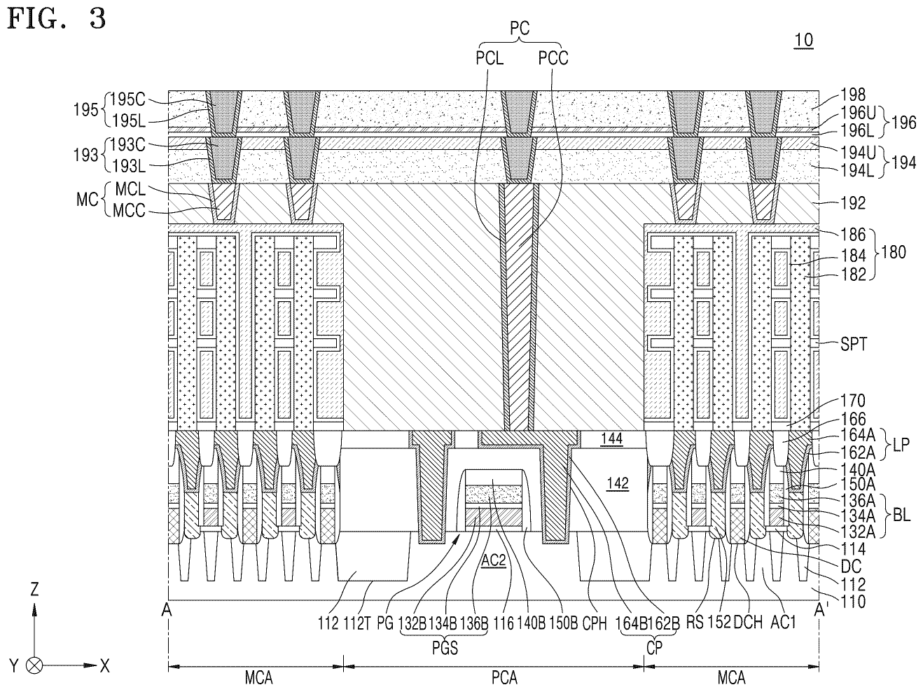

FIG. 1 is a layout diagram showing a semiconductor device 10 according to an embodiment of the present inventive concept. FIG. 2 is an enlarged view of part EX1 of FIG. 1. FIG. 3 is a cross-sectional view taken along line A-A′ in FIG. 2.

Referring to FIGS. 1 to 3, the semiconductor device 10 may include a substrate 110 having memory cell regions MCA and a peripheral circuit region PCA surrounding the memory cell regions MCA.

The memory cell region MCA may be a memory cell region of dynamic random access memory (DRAM). The memory cell region MCA may include a plurality of unit memory cells having transistors and capacitors. The peripheral circuit region PCA may be a core region or peripheral circuit region of the DRAM. The peripheral circuit region PCA may be a region where peripheral circuits required to drive memory cells in the memory cell region MCA are disposed. For example, the peripheral circuit region PCA may include a peripheral circuit transistor PG for transferring signals and/or power to a memory cell region included in the memory cell region MCA. In an embodiment of the present inventive concept, the peripheral circuit transistor PG may configure various circuits such as a command decoder, a control logic, an address buffer, a row decoder, a column decoder, a sense amplifier, and a data input/output circuit.

A device isolation trench 112T may be formed in the substrate 110, and a device isolation film 112 may be formed within the device isolation trench 112T. The device isolation film 112 may include, for example, an oxide film, a nitride film, or a combination thereof. A plurality of first active regions AC1 are defined in the memory cell region MCA on the substrate 110 by the device isolation film 112, and a second active region AC2 is defined in the peripheral circuit region PCA on the substrate 110. For example, the device isolation trench 112T may be arranged on the substrate 110 to surround the plurality of first active regions AC1 in each memory cell region MCA and the plurality of second active regions AC2 in each peripheral circuit region PCA.

In the memory cell region MCA, the plurality of first active regions AC1 may be arranged to have long axes diagonally with respect to a first horizontal direction (X direction) and a second horizontal direction (Y direction). Thus, the second horizontal direction (Y direction) is orthogonal to the first horizontal direction (X direction). The plurality of first active regions AC1 may be disposed in a bar-like form of diagonal lines or oblique lines, as illustrated, and by depositing the plurality of first active regions AC1 in a direction of a diagonal line or an oblique line, a maximum possible distance between contacts may be provided for the semiconductor device 10. A plurality of word lines WL may be spaced apart from each other in the second horizontal direction (Y direction) and extend parallel to each other in the first horizontal direction (X direction) across the plurality of first active regions AC1. The plurality of word lines WL may be arranged at a uniform pitch. A plurality of bit lines BL may extend parallel to each other in the second horizontal direction (Y direction) on the plurality of word lines WL, and may be arranged at a uniform pitch. The plurality of bit lines BL may be connected to the plurality of first active regions AC1 through a plurality of direct contacts DC. The direct contacts DC may each be arranged on a center region of the first active region AC1 in a plan view.

A plurality of buried contacts BC may each be formed between two adjacent bit lines BL among the plurality of bit lines BL, and may be arranged on both ends of the plurality of first active regions AC1. In an embodiment of the present inventive concept, the plurality of buried contacts BC may be arranged in a line in the first horizontal direction (X direction) and the second horizontal direction (Y direction). A plurality of landing pads LP may be disposed on the plurality of buried contacts BC. The plurality of buried contacts BC and the plurality of landing pads LP may connect a lower electrode 182 of a capacitor structure 180 formed on the plurality of bit lines BL to the plurality of first active regions AC1. For example, the plurality of landing pads LP may be arranged between the plurality of buried contacts BC and the lower electrodes 182 of the capacitor structures CAP. At least a portion of each of the plurality of landing pads LP may overlap the buried contact BC in a vertical direction (Z direction).

The substrate 110 may include at least one selected from, for example, silicon (Si), germanium (Ge), silicon germanium (SiGe), silicon carbide (SiC), gallium arsenide (GaAs), indium arsenide (InAs), indium antimonide (InSb), lead telluride (PbTe), gallium phosphide (GaP), gallium antimonide (GaSb), or indium phosphide (InP). The substrate 110 may include a conductive region, for example, a well doped with an impurity or a structure doped with an impurity.

In the memory cell region MCA, a plurality of word line trenches extending in the first horizontal direction (X direction) may be formed in the substrate 110, and a plurality of gate dielectric layers, a plurality of gate electrodes, and a plurality of capping insulating films may be formed in the plurality of word line trenches. The plurality of gate electrodes may correspond to the plurality of word lines WL illustrated in FIG. 1. The plurality of gate dielectric film may include, for example, silicon oxide (SiO₂), silicon nitride (Si₃N₄), silicon oxynitride (SiON), oxide/nitride/oxide (ONO), or a high-k dielectric material having a dielectric constant higher than that of silicon oxide (SiO₂). The high-k dielectric material may include, for example, hafnium oxide (HfO₂), aluminum oxide (Al₂O₃), hafnium aluminum oxide (HfAlO₃), tantalum oxide (Ta₂O₃), lanthanum oxide (La₂O₃), lanthanum aluminum oxide (LaAlO₃), zirconium oxide (ZrO₂), yttrium oxide (Y₂O₃) or titanium oxide (TiO₂), but the present inventive concept is not limited thereto. The plurality of gate electrodes may include, for example, titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or any combination thereof. The plurality of capping insulating films may include a silicon oxide (SiO₂) film, a silicon nitride (Si₃N₄) film, a silicon oxynitride (SON) film, or any combination thereof.

A buffer film 114 may be disposed on the substrate 110 in the memory cell region MCA. The buffer film 114 may include, for example, an oxide film, a nitride film, or any combination thereof.

The plurality of direct contacts DC may be formed within the plurality of direct contact holes DCH of the substrate 110. The direct contact DC may extend to a level higher than an upper surface of the substrate 110. The plurality of direct contacts DC may be connected to the plurality of first active regions AC1. The plurality of direct contacts DC may each include, for example, silicon (Si), germanium (Ge), tungsten (W), tungsten nitride (WN), cobalt (Co), nickel (Ni), aluminum (Al), molybdenum (Mo), ruthenium (Ru), titanium (Ti), titanium nitride (TiN), tantalum (Ta), tantalum nitride (TaN), copper (Cu), or any combination thereof. In an embodiment of the present inventive concept, each of the plurality of direct contacts DC may include doped polysilicon (p-Si). For example, the plurality of direct contacts DC may include polysilicon (p-Si) including a relatively high concentration of impurities such as phosphorus (P), arsenic (As), bismuth (Bi), and antimony (Sb).

The plurality of bit lines BL extending in parallel with each other in the second horizontal direction (Y direction) may be disposed on the substrate 110 and on each of the plurality of direct contacts DC. The plurality of bit lines BL may each be connected to the plurality of first active regions AC1 through the plurality of direct contacts DC. Each of the plurality of bit lines BL may include a lower conductive layer 132A, a middle conductive layer 134A, and an upper conductive layer 136A sequentially stacked on the substrate 110. An upper surface of the lower conductive layer 132A may be located at a vertical level the same as that of an upper surface of the direct contact DC, and a lower surface of the middle conductive layer 134A may be in contact with the upper surface of the direct contact DC.

The lower conductive layer 132A may include, for example, doped polysilicon (p-Si). The middle conductive layer 134A and the upper conductive layer 136A may each include, for example, titanium (Ti), titanium nitride (TiN), titanium silicon nitride (TiSiN), tungsten (W), tungsten nitride (WN), tungsten silicide (WSiₓ), tungsten silicon nitride (WSiₓN_{y}), ruthenium (Ru), or any combination thereof. For example, the middle conductive layer 134A may include a film including, for example, titanium nitride (TiN) and/or titanium silicon nitride (TiSiN), and the upper conductive layer 136A may include a film including, for example, titanium (Ti), titanium nitride (TiN), tungsten (W), tungsten nitride (WN), tungsten silicon nitride (WSiₓN_{y}), ruthenium (Ru), or any combination thereof.

In FIG. 3, each of the plurality of bit lines BL is illustrated as having a triple conductive layer structure including the lower conductive layer 132A, the middle conductive layer 134A, and the upper conductive layer 136A, but the present inventive concept is not limited thereto. For example, the plurality of bit lines BL may each be formed of a single conductive layer, or formed in a stacked structure of a plurality of conductive layers, such as a double conductive layer, or a quadruple conductive layer or more.

An upper surface of each of the plurality of bit lines BL may be respectively covered with each of a plurality of insulating capping layers 140A. The plurality of insulating capping layers 140A may be disposed on the upper conductive layers 136A of the plurality of bit lines BL. The plurality of insulating capping layers 140A may each extend in the second horizontal direction (Y direction) on each of the plurality of bit lines BL. Each of the plurality of insulating capping layers 140A may include a silicon nitride (Si₃N₄) film.

Insulating spacers 150A may be disposed on both sidewalls of each of the plurality of bit lines BL and the plurality of insulating capping layers 140A. The insulating spacer 150A may extend in the second horizontal direction (Y direction) on each of the both sidewalls of the plurality of bit lines BL. Some of the insulating spacers 150A may extend further into the direct contact hole DCH and cover both sidewalls of the direct contact DC formed in the direct contact hole DCH.

A plurality of recess spaces RS formed in the first active regions AC1 in some regions of the substrate 110 may be filled with a plurality of contact plugs 152. Each of the plurality of contact plugs 152 may extend from the recess space RS in the vertical direction (Z direction). Each of the plurality of contact plugs 152 may contact the first active region AC1. The plurality of contact plugs 152 may be arranged in a row in the second horizontal direction (Y direction) between each of the plurality of bit lines BL. For example, each of the plurality of contact plugs 152 may be placed between two adjacent insulating spacers 150A, and the upper side of each of the plurality of contact plugs 152 may be in contact with the two adjacent insulating spacers 150A. The lower side of each of the plurality of contact plugs 152 may extend into the substrate 110. The plurality of contact plugs 152 may form the plurality of buried contacts BC illustrated in FIG. 2. The plurality of contact plugs 152 may include a semiconductor pattern doped with impurities, for example, doped polysilicon (p-Si), but the present inventive concept is not limited thereto.

A plurality of insulating fences may each be disposed between two adjacent ones of the plurality of contact plugs 152 arranged in a row in the second horizontal direction (Y direction). The plurality of contact plugs 152 may be insulated from each other by the plurality of insulating fences. Each of the plurality of insulating fences may have a pillar shape extending in a vertical direction (Z direction) between the plurality of bit lines BL. In an embodiment of the present inventive concept, the plurality of insulating fences may include, for example, a silicon nitride (Si₃N₄) film.

A plurality of landing pads LP may be disposed on the plurality of contact plugs 152. Each of the plurality of landing pads LP may extend in the vertical direction (Z direction) on the contact plug 152. Each of the plurality of landing pads LP may include a conductive barrier film 162A and a landing pad conductive layer 164A. In an embodiment of the present inventive concept, the conductive barrier film 162A may include, for example, titanium (Ti), titanium nitride (TiN), or any combination thereof, and the landing pad conductive layer 164A may include, for example, a metal, a metal nitride, conductive polysilicon (p-Si), or any combination thereof. The plurality of landing pads LP may have an island pattern shape in a plan view. The plurality of landing pads LP may be electrically insulated from each other by an insulating pattern 166 surrounding each of the plurality of landing pads LP. The insulating pattern 166 may include at least one of, for example, silicon nitride (Si₃N₄), silicon oxide (SiO₂), or silicon oxynitride (SiON).

A metal silicide film may further be disposed between the plurality of contact plugs 152 and the plurality of landing pads LP. The metal silicide film may include, for example, cobalt silicide (CoSi₂), nickel silicide (NiSi₂), titanium silicide (TiSi₂), tantalum silicide (TaSi₂), or manganese silicide (MnSi₂).

In the peripheral circuit region PCA, a peripheral circuit transistor PG may be disposed on the second active region AC2. The peripheral circuit transistor PG may include a gate dielectric film 116, a gate electrode PGS, and a gate capping layer 140B sequentially stacked on the second active region AC2.

The gate dielectric film 116 may include at least one selected from silicon oxide (SiO₂), silicon nitride (Si₃N₄), silicon oxynitride (SON), or a high dielectric material having a dielectric constant higher than that of silicon oxide (SiO₂). The high-k dielectric film may include, for example, hafnium oxide (HfO₂), aluminum oxide (Al₂O₃), hafnium aluminum oxide (HfAlO₃), tantalum oxide (Ta₂O₃), lanthanum oxide (La₂O₃), lanthanum aluminum oxide (LaAlO₃), zirconium oxide (ZrO₂), yttrium oxide (Y₂O₃) or titanium oxide (TiO₂), but the present inventive concept is not limited thereto.

The gate electrode PGS may include a lower conductive layer 132B, a middle conductive layer 134B, and an upper conductive layer 136B. A material constituting each of the lower conductive layer 132B, the middle conductive layer 134B, and the upper conductive layer 136B may be substantially the same as the material constituting each of the lower conductive layer 132A, the middle conductive layer 134A, and the upper conductive layer 136A included in the bit line BL located in the memory cell region MCA. For example, the gate electrode PGS may be simultaneously formed in a process of forming the bit lines BL. However, the present inventive concept is not limited thereto.

In an embodiment of the present inventive concept, the gate capping layer 140B may include silicon nitride (Si₃N₄).

In an embodiment of the present inventive concept, both sidewalls of the gate electrode PGS may be covered with gate spacers 150B. The gate spacer 150B may include, for example, silicon oxide (SiO₂), silicon nitride (Si₃N₄), or any combination thereof.

The peripheral circuit transistor PG may be covered with a first insulating film 142. A second insulating film 144 may be disposed on the first insulating film 142. In the peripheral circuit region PCA, a contact plug CP may be formed in the contact hole CPH penetrating the first insulating film 142 and the second insulating film 144 in the vertical direction (Z direction). The contact plug CP may include a conductive barrier film 162B and a plug conductive layer 164B. Each of the conductive barrier film 162B and the plug conductive layer 164B of the contact plug CP may have a structure that is substantially the same or similar to each of the conductive barrier film 162A and the landing pad conductive layer 164A of the plurality of landing pads LP formed in the memory cell region MCA and may include substantially the same material. As shown in FIG. 3, contact plugs CP may be respectively formed in contact holes CPH penetrating the first insulating film 142 and the second insulating film 144 in the vertical direction (Z direction) in the peripheral circuit region PCA to be connected to the substrate 110. For example, the contact plugs CP may be disposed adjacent to the gate electrode PGS and connected to the source and drain regions of the substrate 110.

In the memory cell region MCA, an upper insulating pattern 170 may be disposed on the insulating pattern 166. The upper insulating pattern 170 may include a material that has an etch selectivity with respect to the second insulating film 144 and the insulating pattern 166. For example, the upper insulating pattern 170 may include silicon nitride (Si₃N₄).

In the memory cell region MCA, a capacitor structure 180 may be disposed on the upper insulating pattern 170 and the landing pads LP to store electric charges in, for example, a semiconductor memory element. For example, the capacitor structure 180 may be connected to a portion of the upper surface of each of the landing pads LP which is not blocked by the upper insulating pattern 170. The capacitor structure 180 may include a plurality of lower electrodes 182, a capacitor dielectric film 184, and an upper electrode 186. The capacitor structure 180 may be formed only in the memory cell region MCA. That is, the plurality of lower electrodes 182, the capacitor dielectric film 184, and the upper electrode 186 of the capacitor structure 180 may not be formed in the peripheral circuit region PCA.

The plurality of lower electrodes 182 may be disposed on the plurality of landing pads LP. The plurality of lower electrodes 182 may extend in the vertical direction (Z direction) through the upper insulating pattern 170 on the plurality of landing pads LP. A lower surface of one of the plurality of lower electrodes 182 may contact one landing pad LP selected from the plurality of landing pads LP. The one of the plurality of lower electrodes 182 may be in contact with the one landing pad LP and connected to the one landing pad LP. Each of the plurality of lower electrodes 182 may include, for example, a metal, a conductive metal oxide, a conductive metal nitride, a conductive metal oxynitride, or any combination thereof. In an embodiment of the present inventive concept, the plurality of lower electrodes 182 may include at least one selected from a metal such as, for example, ruthenium (Ru), titanium (Ti), tantalum (Ta), niobium (Nb), iridium (Ir), molybdenum (Mo), tungsten (W), etc., a conductive metal nitride such as, for example, titanium nitride (TiN), tantalum nitride (TaN), niobium nitride (NbN), molybdenum nitride (MoN), tungsten nitride (WN), etc., and a conductive metal oxide such as, for example, iridium oxide (IrO₂), ruthenium oxide (RuO₂), strontium ruthenium oxide (SrRuO₃), etc.

A plurality of support layers SPT may be disposed on sidewalls of the plurality of lower electrodes 182. The plurality of support layers SPT may maintain a constant distance between two adjacent lower electrodes 182 and prevent the plurality of lower electrodes 182 from tilting or falling. The plurality of support layers SPT may be located at different vertical levels on the sidewalls of the plurality of lower electrodes 182.

The capacitor dielectric film 184 may be disposed on the plurality of lower electrodes 182. The capacitor dielectric film 184 may cover the sidewalls of the plurality of lower electrodes 182, the upper and lower surfaces of the support layer SPT, and the upper surface of the upper insulating pattern 170. The capacitor structure 180 may store electric charges in the capacitor dielectric film 184 by a potential difference generated between the lower electrode 182 and the upper electrode 186. The capacitor dielectric film 184 may include, for example, zirconium oxide (ZrO₂), hafnium oxide (HfO₂), titanium oxide (TiO₂), niobium oxide (Nb₂O₅), tantalum oxide (Ta₂O₃), yttrium oxide (Y₂O₃), strontium titanium oxide (SrTiO₃), barium strontium titanium oxide (BaSrTi₂O₆), scandium oxide (Sc₂O₃), lanthanide oxide (La₂O₃), or any combination thereof.

The plurality of upper electrodes 186 may be arranged to cover the plurality of lower electrodes 182 on the capacitor dielectric film 184. The plurality of upper electrodes 186 may each include, for example, metal, conductive metal oxide, conductive metal nitride, conductive metal oxynitride, or any combination thereof. In an embodiment of the present inventive concept, the plurality of upper electrodes 186 may include at least one selected from a metal such as, for example, ruthenium (Ru), titanium (Ti), tantalum (Ta), niobium (Nb), iridium (Ir), molybdenum (Mo), tungsten (W), etc., a conductive metal nitride such as, for example, titanium nitride (TiN), tantalum nitride (TaN), niobium nitride (NbN), molybdenum nitride (MoN), tungsten nitride (WN), etc., or a conductive metal oxide such as, for example, iridium oxide (IrO₂), ruthenium oxide (RuO₂), strontium ruthenium oxide (SrRuO₃), etc.

A lower insulating film 192 may be disposed on the substrate in the memory cell region MCA and the peripheral circuit region PCA. The lower insulating film 192 may cover the capacitor structure 180 in the memory cell region MCA. The lower insulating film 192 may be disposed on the second insulating film 144 and the contact plug CP in the peripheral circuit region PCA. The lower insulating film 192 may cover the second insulating film 144 and the contact plug CP. The lower insulating film 192 may fill a space between the capacitor structures 180 of each of two adjacent memory cell regions MCAs.

In an embodiment of the present inventive concept, the lower insulating film 192 may include an oxide. For example, the lower insulating film 192 may include tetraethyl orthosilicate (TEOS), low deposition-tetraethyl orthosilicate (LD-TEOS), plasma enhanced-tetraethyl orthosilicate (PE-TEOS), or any combination thereof.

A plurality of cell contacts MC may extend in the vertical direction (Z direction) through the lower insulating film 192 in the memory cell region MCA. A bottom surface of each of the plurality of cell contacts MC may be connected to the upper electrode 186 of the capacitor structure 180. Each of the plurality of cell contacts MC may include a cell conductive barrier film MCL and a cell contact conductive layer MCC. The plurality of cell contacts MC may have a circular shape in a plan view.

A peripheral circuit contact PC may extend in the vertical direction (Z direction) through the lower insulating film 192 in the peripheral circuit region PCA. The peripheral circuit contact PC may have a circular shape in a plan view. A bottom surface of the peripheral circuit contact PC may be in contact with the contact plug CP and connected to the contact plug CP. The peripheral circuit contact PC may be connected to the second active region AC2 through the contact plug CP. The peripheral circuit contact PC may include a peripheral circuit conductive barrier film PCL and a peripheral circuit contact conductive layer PCC.

A plurality of wiring lines 193 and a first interlayer insulating film 194 covering the plurality of wiring lines 193 may be disposed on the plurality of cell contacts MC, the peripheral circuit contacts PC, and the lower insulating film 192. Bottom surfaces of the plurality of wiring lines 193 may be in contact with upper surfaces of the plurality of cell contacts MC and the peripheral circuit contact PC.

Each of the plurality of wiring lines 193 may include a wiring line conductive layer 193C and a wiring line barrier layer 193L. In an embodiment of the present inventive concept, the wiring line conductive layer 193C may include tungsten (W), copper (Cu), aluminum (Al), cobalt (Co), molybdenum (Mo), ruthenium (Ru), titanium (Ti), tantalum (Ta), titanium nitride (TiN), tantalum nitride (TaN), or any combination thereof. For example, the wiring line conductive layer 193C may include a copper (Cu) film. The wiring line barrier layer 193L may include tantalum (Ta), tantalum nitride (TaN), titanium (Ti), titanium nitride (TiN), or any combination thereof, but the present inventive concept is not limited thereto.

In an embodiment of the present inventive concept, the first interlayer insulating film 194 may include a first lower interlayer insulating film 194L and a first upper interlayer insulating film 194U that are sequentially stacked on the lower insulating film 192.

In an embodiment of the present inventive concept, a vertical direction (Z direction) thickness (i.e., vertical thickness) of the first upper interlayer insulating film 194U may be smaller than a vertical direction (Z direction) thickness (i.e., vertical thickness) of the first lower interlayer insulating film 194L. However, the present inventive concept is not limited thereto, and the thickness of the first upper interlayer insulating film 194U in the vertical direction (Z direction) may be greater than or equal to the vertical (Z direction) thickness of the first lower interlayer insulating film 194L.

In an embodiment of the present inventive concept, the first lower interlayer insulating film 194L may include a low-k material. For example, the first lower interlayer insulating film 194L may include a low dielectric constant K in a range from about 2.2 to about 3.0. For example, the first lower interlayer insulating film 194L may include, for example, a silicon oxycarbide (SiOC) film or a carbon doped silicon oxide (SiCOH) film.

In an embodiment of the present inventive concept, the first upper interlayer insulating film 194U may include a low dielectric material including a benzene ring. For example, the first upper interlayer insulating film 194U may include a material represented by Chemical Formula 1 below.

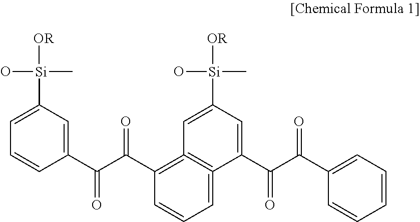

In Chemical Formula 1, R represents an alkyl group, and O—Si— represents Chemical Formula 1 being repeatedly linked to Chemical Formula 1 through SiO bond.

The first upper interlayer insulating film 194U includes a low dielectric material including a benzene ring, therefore outgassing of impurities (e.g., H₂O, H⁺) generated in an interlayer insulating film (e.g., including TEOS) during a manufacturing process of a conventional semiconductor device may be prevented. If outgassing of impurities occurs in the interlayer insulating film, a defect in an upper contact may occur and, as a result, the reliability of the semiconductor device may be reduced.

The first upper interlayer insulating film 194U of the semiconductor device 10 of the present inventive concept includes a material represented by Chemical Formula 1, and because the material does not generate impurities, the outgassing phenomenon may be prevented. Because the outgassing phenomenon of the first upper interlayer insulating film 194U is prevented, formation of a defect in the upper contact 195 may be prevented, and productivity and reliability of the semiconductor device 10 may be enhanced.

In an embodiment of the present inventive concept, the first upper interlayer insulating film 194U may include a material having a dielectric constant lower than that of the lower insulating film 192. For example, the first upper interlayer insulating film 194U may include a material having a dielectric constant lower than that of TEOS, PE-TEOS, LD-TEOS, or any combination thereof. For example, the lower insulating film 192 may include a material having a dielectric constant greater than a dielectric constant of a material of the first upper interlayer insulating film.

The first upper interlayer insulating film 194U includes a material with a dielectric constant lower than that of TEOS, PE-TEOS, LD-TEOS, or a combination thereof, therefore preventing deterioration between the wiring lines 193, and the electrical performance and integration of the semiconductor device 10 may be enhanced.

In an embodiment of the present inventive concept, the first lower interlayer insulating film 194L may include a material having a dielectric constant different from that of the first upper interlayer insulating film 194U. The first lower interlayer insulating film 194L may include a material having a dielectric constant lower than that of the lower insulating film 192. For example, the first lower interlayer insulating film 194L may include a material having a dielectric constant lower than that of TEOS, PE-TEOS, LD-TEOS, or any combination thereof.

In an embodiment of the present inventive concept, the first lower interlayer insulating film 194L and the first upper interlayer insulating film 194U may include the same type of low-k dielectric material. The same type of low-k dielectric materials described here may include, for example, silicon oxycarbide (SiOC), carbon doped silicon oxide (SiCOH) and materials represented by Chemical Formula 1. In an embodiment of the present inventive concept, the first lower interlayer insulating film 194L and the first upper interlayer insulating film 194U may include the same material. Because the first lower interlayer insulating film 194L and the first upper interlayer insulating film 194U include the same low dielectric material, sidewalls of the wiring line 193 may be coplanar in a region adjacent to a boundary where the first lower interlayer insulating film 194L contacts the first upper interlayer insulating film 194U. For example, the sidewall of the wiring line 193 may extend as a straight line (or plane) passing through the boundary between the first lower interlayer insulating film 194L and the first upper interlayer insulating film 194U. The sidewall of the wiring line 193 may be located on an inclined plane. Because the first lower interlayer insulating film 194L and the first upper interlayer insulating film 194U include the same low dielectric material, voids may not be generated in the wiring lines 193 during a forming operation of the wiring lines 193. Because voids are removed from the wiring line 193, the electrical performance and integration of the semiconductor device 10 may be enhanced. In an embodiment of the present inventive concept, the first lower interlayer insulating film 194L of the semiconductor device 10 of the present inventive concept may also include a material represented by Chemical Formula 1. However, the present inventive concept is not limited thereto.

An interlayer capping layer 196 may be disposed on the plurality of wiring lines 193 and the first interlayer insulating film 194. The interlayer capping layer 196 may include a lower capping layer 196L covering the first interlayer insulating film 194 and an upper capping layer 196U covering the lower capping layer 196L. A bottom surface of the lower capping layer 196L may contact an upper surface of each of the plurality of wiring lines 193 and the first interlayer insulating film 194. The lower capping layer 196L is disposed between the upper capping layer 196U and the first interlayer insulating film 194, therefore enhancing the adhesion between the upper capping layer 196U and the first interlayer insulating film 194.

In an embodiment of the present inventive concept, the interlayer capping layer 196 may include, for example, silicon nitride (Si₃N₄) or silicon carbonitride (SiCN). For example, the upper capping layer 196U may include silicon nitride (Si₃N₄), and the lower capping layer 196L may include silicon carbonitride (SiCN).

A second interlayer insulating film 198 may be disposed on the interlayer capping layer 196. In an embodiment of the present inventive concept, the second interlayer insulating film 198 may include a material having a dielectric constant higher than that of the first upper interlayer insulating film 194U. For example, the second interlayer insulating film 198 may include, for example, TEOS, PE-TEOS, LD-TEOS, or any combination thereof.

A plurality of upper contacts 195 may be disposed to penetrate the interlayer capping layer 196 and the second interlayer insulating film 198 in the vertical direction (Z direction). The plurality of upper contacts 195 may each be electrically connected to each of the plurality of wiring lines 193, respectively, through the second interlayer insulating film 198 and the interlayer capping layer 196.

In an embodiment of the present inventive concept, the plurality of upper contacts 195 may each include an upper contact conductive layer 195C and an upper contact barrier layer 195L. In an embodiment of the present inventive concept, the upper contact conductive layer 195C may include, for example, tungsten (W), copper (Cu), aluminum (Al), cobalt (Co), molybdenum (Mo), ruthenium (Ru), titanium (Ti), tantalum (Ta), titanium nitride (TiN), tantalum nitride (TaN), or any combination thereof. For example, the upper contact conductive layer 195C may include, for example, a copper (Cu) film. The upper contact barrier layer 195L may include, for example, tantalum (Ta), tantalum nitride (TaN), titanium (Ti), titanium nitride (TiN), or any combination thereof, but the present inventive concept is not limited thereto.

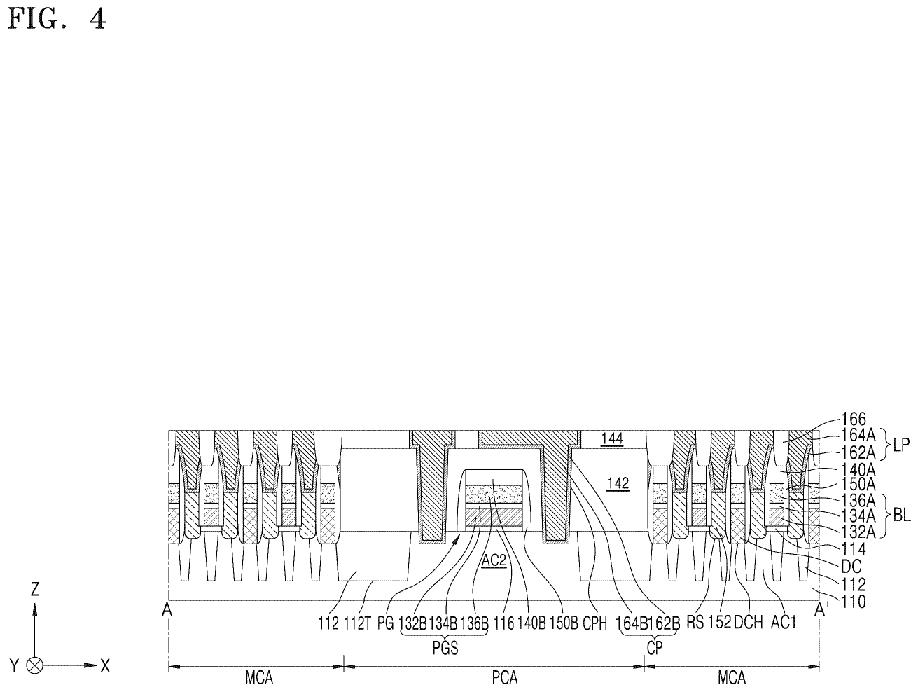

FIGS. 4 to 14 are cross-sectional views for explaining a method of manufacturing the semiconductor device 10 according to an embodiment of the present inventive concept. For example, FIGS. 4 to 14 are cross-sectional views for explaining each operation of the method of manufacturing the semiconductor device 10 according to an embodiment of the present inventive concept.

Referring to FIG. 4, the plurality of device isolation trenches 112T may be formed in the substrate 110 having the memory cell region MCA and the peripheral circuit region PCA. Next, the plurality of device isolation films 112 may be formed by filling the plurality of device isolation trenches 112T with an insulating material. By the forming of the plurality of device isolation films 112, the plurality of first active regions AC1 may be defined in the memory cell region MCA of the substrate 110, and the second active region AC2 may be defined in the peripheral circuit region PCA. In a plan view, the plurality of first active regions AC1 may extend in a diagonal direction (see FIG. 2) inclined at a predetermined angle with the first horizontal direction (X direction) and the second horizontal direction (Y direction). In addition, the plurality of first active regions AC1 may be in the form of a plurality of bars extending parallel to each other, and the substantially center portion of one of the plurality of first active regions AC1 may be disposed adjacent to an end portion of another first active region AC1.

Next, a buffer film 114 may be formed in the memory cell region MCA of the substrate 110, and a gate dielectric film 116 may be formed in the peripheral circuit region PCA of the substrate 110.

Next, the direct contact hole DCH may be formed by removing a portion of the substrate 110 using a mask pattern. The direct contact hole DCH may expose the first active region AC1. The mask pattern may include, for example, an oxide film, a nitride film, or any combination thereof, but the present inventive concept is not limited thereto. Thereafter, the mask pattern is removed, and a direct contact DC may be formed by filling the direct contact hole DCH with a conductive material. For example, the direct contact holes DCH may each be formed at the substantially center portion of each of the first active regions AC1.

Next, the lower conductive layer 132A, the middle conductive layer 134A, the upper conductive layer 136A, and the insulating capping layer 140A are sequentially formed on the buffer film 114 and the direct contact DC in the memory cell region MCA, and the lower conductive layer 132B, the middle conductive layer 134B, the upper conductive layer 136B, and the insulating capping layer 140B are sequentially formed on the gate dielectric film 116 in the peripheral circuit region PCA.

Next, in the memory cell region MCA, the plurality of bit lines BL are formed by etching a portion of each of the direct contact DC, the lower conductive layer 132A, the middle conductive layer 134A, and the upper conductive layer 136A using the insulating capping layer 140A as an etch mask, and in the peripheral circuit region PCA, a gate electrode PGS may be formed by etching a portion of each of the lower conductive layer 132B, the middle conductive layer 134B, and the upper conductive layer 136B using the insulating capping layer 140B as an etch mask. For example, after the patterning process, the bit lines BL and the direct contacts DC may be formed on and connected to the substrate 110, and extending in the second horizontal direction (Y direction) in the memory cell regions MCA.

Next, the gate spacer 150B may be formed on the sidewalls of the gate electrode PGS, and the first insulating film 142 covering the gate electrode PGS may be formed.

Next, the insulating spacer 150A may be formed on the sidewalls of each of the plurality of bit lines BL and the insulating capping layer 140A in the memory cell region MCA, and a plurality of insulating fences may be formed between the plurality of bit lines BL. For example, the plurality of insulating fences may be formed using an insulating material at the intersection of a space between two adjacent bit lines BL. The insulating spacer 150A may conformally cover the sidewalls of each of the plurality of bit lines BL and the insulating capping layer 140A.

Next, a plurality of recess spaces RS exposing the first active regions AC1 may be formed between the plurality of bit lines BL by removing a portion of the substrate 110 disposed on a bottom of a contact space between the plurality of bit lines BL and between the plurality of insulating fences. In an embodiment of the present inventive concept, an anisotropic etching process or a combination of an anisotropic etching process and an isotropic etching process may be used to form the plurality of recess spaces RS.

Next, the plurality of contact plugs 152 may be formed by filling the plurality of recess spaces RS and a portion of the contact space with a conductive material.

Next, in the peripheral circuit region PCA, a plurality of contact holes CPH exposing the second active region AC2 may be formed by etching the first insulating film 142.

Next, in the memory cell region MCA and the peripheral circuit region PCA, a conductive barrier film and a conductive layer are formed to cover the exposed surfaces of the substrate 110. Afterwards, the conductive barrier film and the conductive layer are patterned to form a plurality of landing pads LP including the conductive barrier film 162A and the landing pad conductive layer 164A may be formed in the memory cell region MCA, and a plurality of contact plugs CP including the conductive barrier film 162B and the plug conductive layer 164B may be formed in the peripheral circuit region PCA. Each of the plurality of landing pads LP may then be disposed on a portion of an upper surface of the insulating capping layer 140A and on an upper surface of the contact plug 152. Like the contact plugs 152, the landing pads LP may form a plurality of isolated regions spaced apart from each other.

Next, the insulating pattern 166 surrounding the sidewalls of the plurality of landing pads LP and the second insulating film 144 covering the sidewalls of the contact plug CP may be formed. For example, the insulating pattern 166 may separate the landing pads LP from each other, and the second insulating film 144 may separate the contact plugs CP from each other.

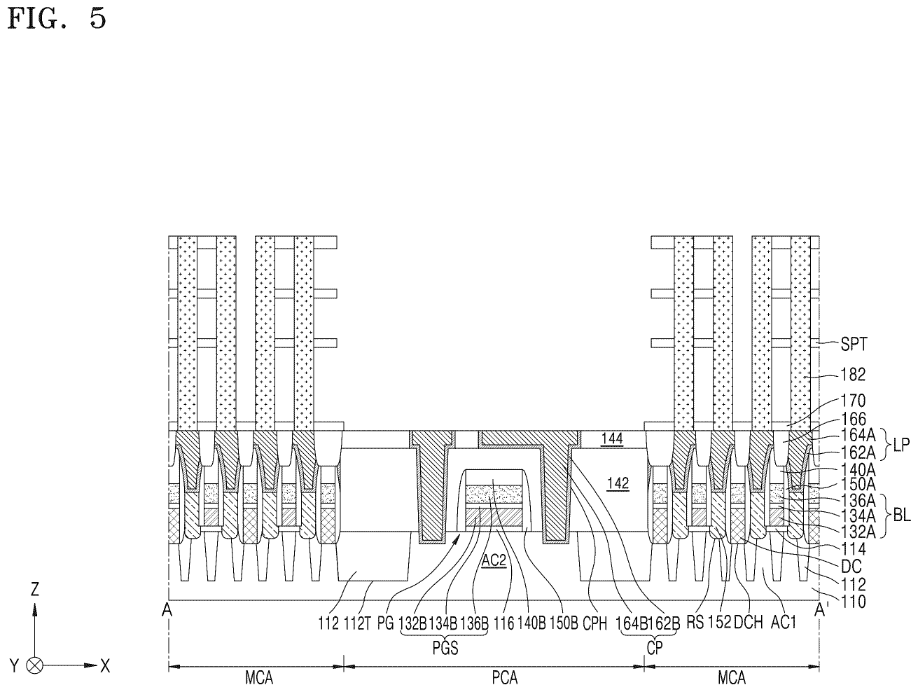

Referring to FIG. 5, the upper insulating pattern 170 may be formed on the insulating pattern 166 in the memory cell region MCA of the substrate 110. Next, a mold structure may be formed on the upper insulating pattern 170. The mold structure may include a first mold layer, a second mold layer, and a third mold layer sequentially stacked on the upper insulating pattern 170.

In an embodiment of the present inventive concept, the support layer SPT may be selectively formed between the first mold layer and the second mold layer, between the second mold layer and the third mold layer, and on the third mold layer. Although it is illustrated that three support layers SPT are formed in FIG. 5, the present inventive concept is not limited thereto, and the number of support layers SPT may vary depending on a height of the plurality of lower electrodes 182.

In an embodiment of the present inventive concept, the support layer SPT may be formed by using a material having an etch selectivity with respect to a material constituting the mold structure. In this case, the etch rate of the material constituting the mold structure may be significantly higher than the etch rate of the material of the support layer SPT under a selected etch condition. For example, the first to third mold layers may be formed using silicon oxide (SiO₂), and the support layer SPT may be formed using silicon nitride (Si₃N₄). However, the present inventive concept is not limited thereto.

Next, a mask pattern is formed on the mold structure, an opening is formed through the mold structure using the mask pattern as an etch mask, and a plurality of lower electrodes 182 may be formed by filling the opening with a conductive material. Each of the plurality of lower electrodes 182 may contact an upper surface of the conductive landing pad LP at a bottom surface.

Next, the mold structure may be removed from the memory cell region MCA, and the mold structure and the support layer SPT may be removed from the peripheral circuit region PCA. In an embodiment of the present inventive concept, a combination of an anisotropic etching process and an isotropic etching process may be used to remove the mold structure and the support layer SPT. In the memory cell region MCA, the mold structure may be removed to expose at least a portion of both sidewalls of the plurality of lower electrodes 182, the upper and lower surfaces of the support layer SPT, and an upper surface of the upper insulating pattern 170. In the peripheral circuit region PCA, the mold structure and the support layer SPT may be removed to expose an upper surface of the second insulating film 144 and an upper surface of the contact plug CP.

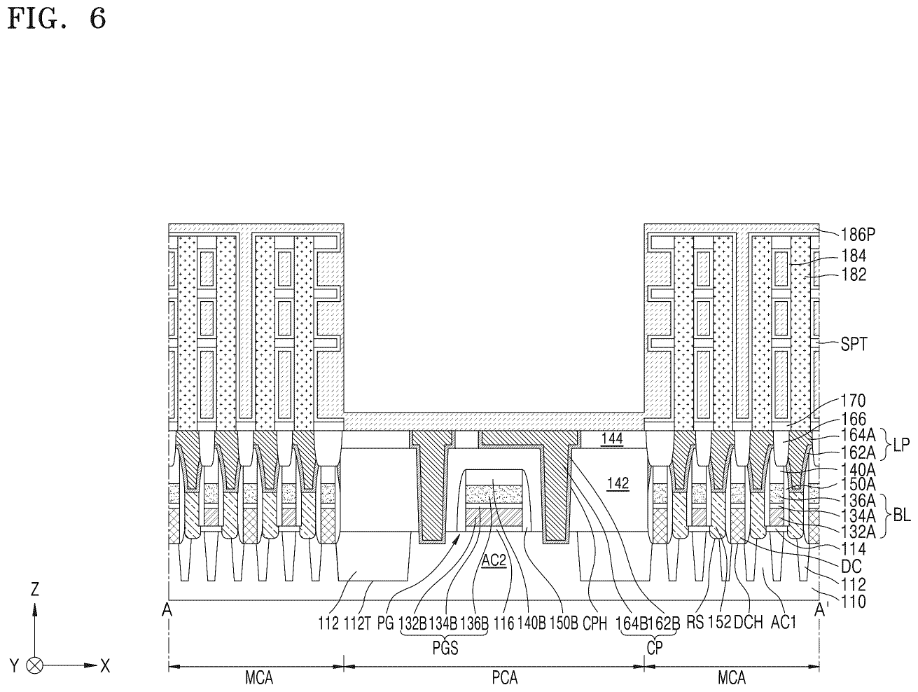

Referring to FIG. 6, the capacitor dielectric film 184 may be formed on the upper insulating pattern 170, the plurality of lower electrodes 182, and the support layer SPT. The capacitor dielectric film 184 may conformally cover the upper surface of the upper insulating pattern 170, at least a portion of both sidewalls of the plurality of lower electrodes 182, and the upper and lower surfaces of the support layer SPT. For example, the capacitor dielectric film 184 may be conformally formed on all the exposed surfaces after the removal of the mold structure in the memory cell region MCA. Next, a preliminary upper electrode layer 186P may be formed to cover the capacitor dielectric film 184, the upper surface of the second insulating film 144, and the upper surface of the contact plug CP.

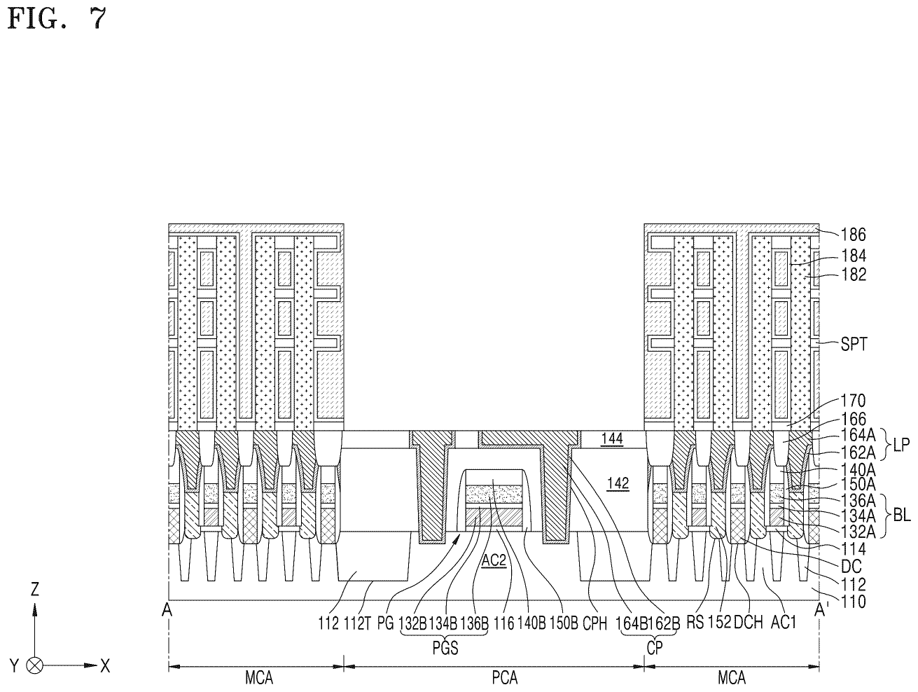

Referring to FIG. 7, a mask pattern is formed on an upper surface of the preliminary upper electrode layer 186P, and a portion of the preliminary upper electrode layer 186P (see FIG. 6) located in the peripheral circuit region PCA may be removed by using the mask pattern as an etch mask. For example, the mask pattern may be a photoresist pattern including a photoresist material layer. The mask pattern may be formed on an upper surface of a portion of the preliminary upper electrode layer 186P located in the memory cell region MCA but may not be formed on the upper surface of the remaining portion of the preliminary upper electrode layer 186P located in the peripheral circuit region PCA. A portion of the preliminary upper electrode layer 186P located in the peripheral circuit region PCA may be removed to expose the upper surface of the second insulating film 144 and the upper surface of the contact plug CP. The removal of the portion of the preliminary upper electrode layer 186P located in the peripheral circuit region PCA may be carried out with an anisotropic etching process using the photoresist pattern as an etching mask. In addition, the remaining portion of the preliminary upper electrode layer 186P that is not removed and remains located in the memory cell region MCA may form the upper electrode 186 of the capacitor structure 180.

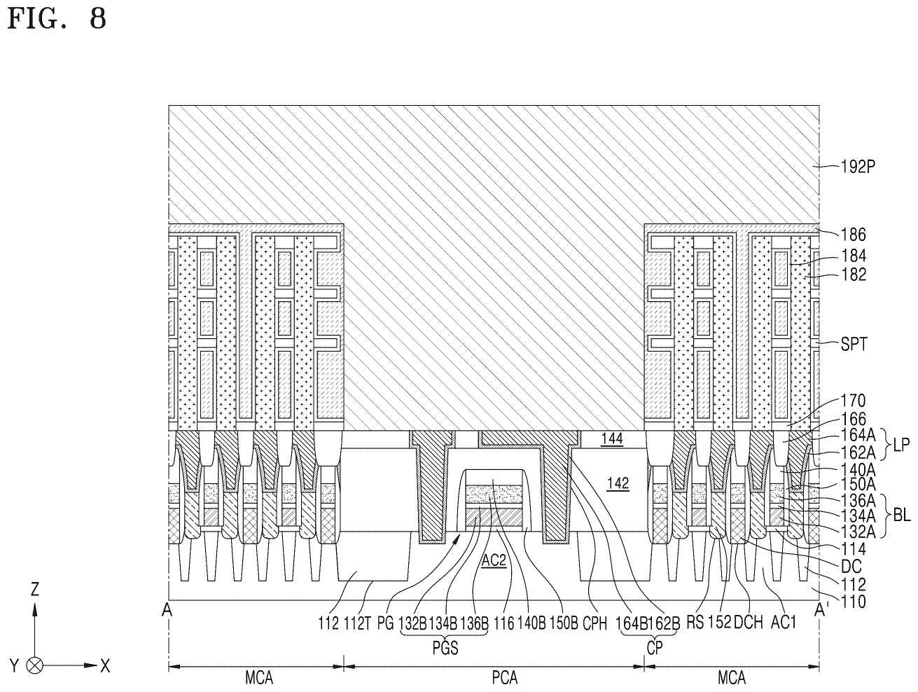

Referring to FIG. 8, a first insulating material layer 192P covering the capacitor structure 180 in the memory cell region MCA and covering the second insulating film 144 and the contact plug CP in the peripheral circuit region PCA may be formed. The first insulating material layer 192P may be formed through a deposition process. In an embodiment of the present inventive concept, the first insulating material layer 192P may include, for example, TEOS, PE-TEOS, LD-TEOS, or any combination thereof.

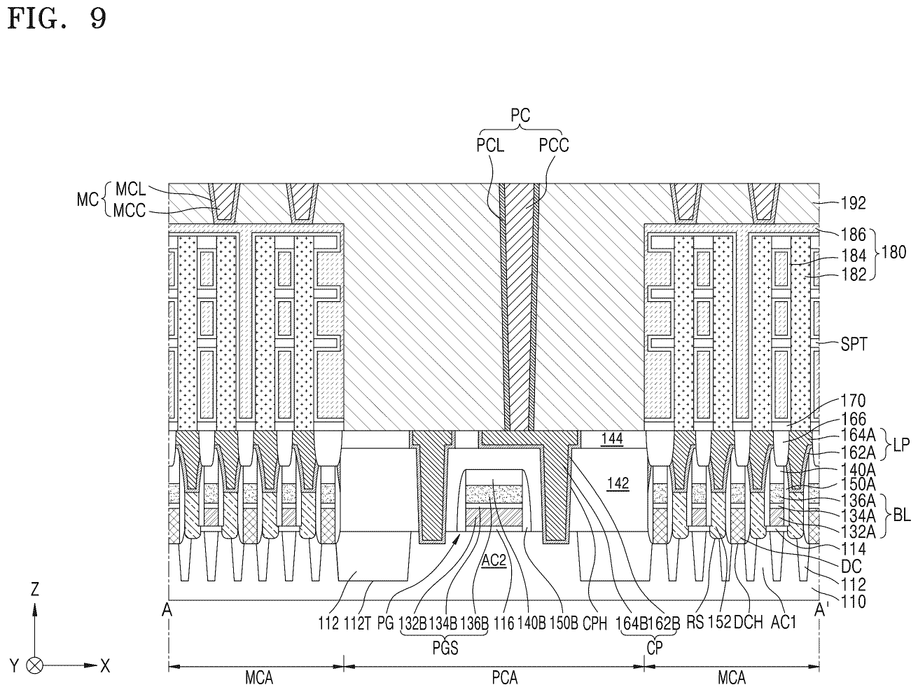

Referring to FIG. 9, an upper surface of the insulating material layer 192P (see FIG. 8) may be flattened through a planarization process. The planarization process may be, for example, a chemical mechanical polishing (CMP) process. A portion of the insulating material layer 192P that remains and is not removed after the planarization process may be the lower insulating film 192.

Next, a plurality of metal contact holes may be formed through the lower insulating layer 192 in the memory cell region MCA, and peripheral circuit contact holes may be formed through the lower insulating film 192 in the peripheral circuit region PCA. The plurality of metal contact holes and the peripheral circuit contact holes may be formed through an etching process.

Next, the conductive barrier film MCL that conformally covers inner walls of the plurality of metal contact holes and a conductive barrier film PCL that conformally covers inner walls of the peripheral circuit contact holes may be formed. The conductive barrier film MCL and the conductive barrier film PCL may include, for example, titanium (Ti), titanium nitride (TiN), or any combination thereof, but the present inventive concept is not limited thereto.

Next, the contact conductive layer MCC filling the plurality of metal contact holes and the peripheral circuit contact conductive layer PCC filling the peripheral circuit contact holes may be formed, and the plurality of metal contacts MC and the peripheral circuit contacts PC may be formed by polishing upper surfaces of the conductive barrier films MCL and PCL and upper surfaces of the contact conductive layers MCC and the peripheral circuit contact conductive layer PCC. For example, a CMP process may used to polish the upper surfaces of the conductive barrier films MCL and PCL and the upper surfaces of the contact conductive layers MCC and the peripheral circuit contact conductive layer PCC.

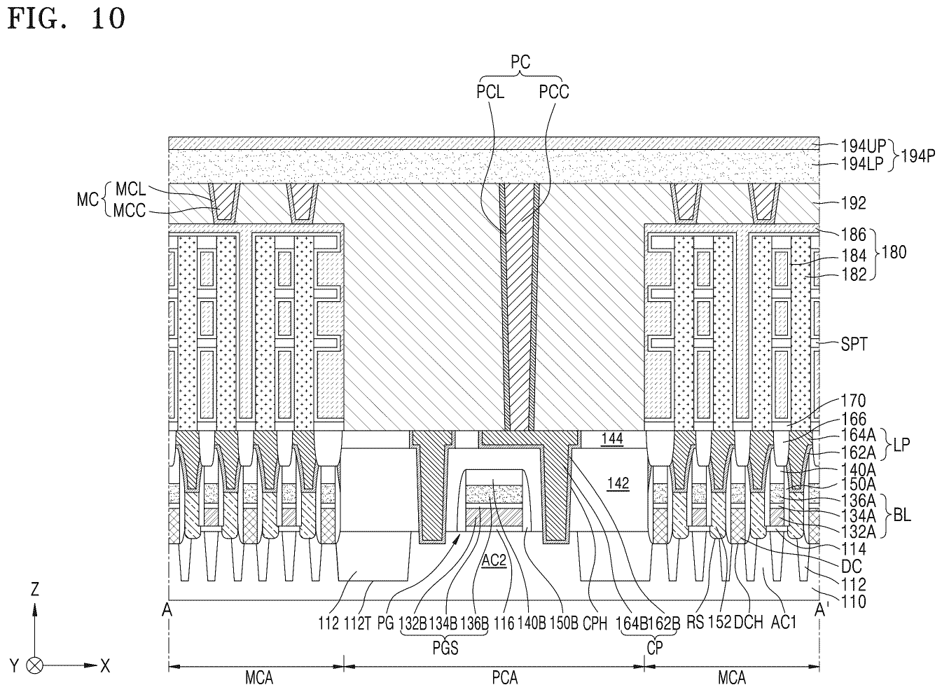

Referring to FIG. 10, a first preliminary interlayer insulating film 194P may be formed. A first preliminary lower interlayer insulating film 194LP may be formed on the plurality of cell contacts MC, the peripheral circuit contacts PC, and lower insulating film 192. In an embodiment of the present inventive concept, the first preliminary lower interlayer insulating film 194LP may include a low-k material. For example, the first preliminary lower interlayer insulating film 194LP may include a low dielectric film having a low dielectric constant K in a range from about 2.2 to about 3.0. For example, the first preliminary lower interlayer insulating film 194LP may include a silicon oxycarbide (SiOC) film or a carbon doped silicon oxide (SiCOH) film.

Next, a first preliminary upper interlayer insulating film 194UP may be formed on the first preliminary lower interlayer insulating film 194LP. The first preliminary upper interlayer insulating film 194UP and the first preliminary lower interlayer insulating film 194LP may constitute the first preliminary interlayer insulating film 194P. In an embodiment of the present inventive concept, the first preliminary upper interlayer insulating film 194UP may include a low dielectric material including a benzene ring. For example, the first preliminary upper interlayer insulating film 194UP may include a material represented by Chemical Formula 1 below.

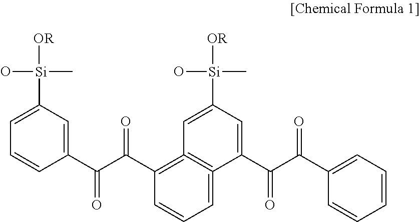

In Chemical Formula 1, R represents an alkyl group, and O—Si— represents Chemical Formula 1 being repeatedly linked to Chemical Formula 1 through SiO bond.

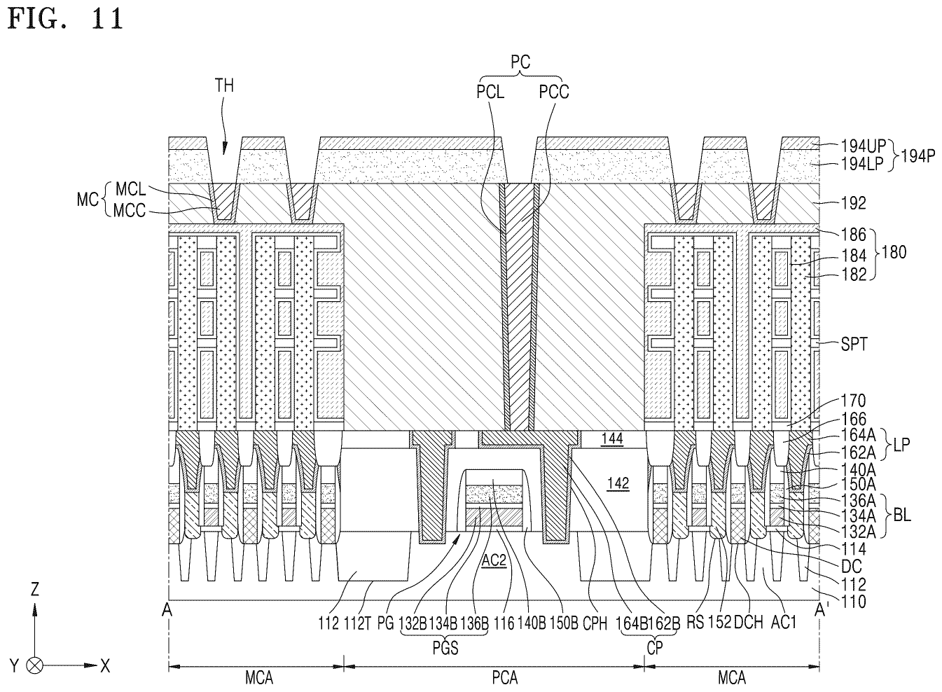

Referring to FIG. 11, next, a plurality of trenches TH penetrating the first preliminary interlayer insulating film 194P may be formed. The plurality of trenches TH may be formed through an etching process. The first preliminary lower interlayer insulating film 194LP and the first preliminary upper interlayer insulating film 194UP may include the same material. Because the first preliminary lower interlayer insulating film 194LP and the first preliminary upper interlayer insulating film 194UP include the same low dielectric material, sidewalls of the trench TH may be coplanar in a region adjacent to a boundary where the first preliminary lower interlayer insulating film 194LP contacts the first preliminary upper interlayer insulating film 194UP. For example, the sidewall of the trench TH may extend as a straight line (or plane) passing through the boundary between the first preliminary lower interlayer insulating film 194LP and the first preliminary upper interlayer insulating film 194UP. The sidewall of the trench TH may be located on an inclined plane. Because the first preliminary lower interlayer insulating film 194LP and the first preliminary upper interlayer insulating film 194UP include the same low dielectric material, an etch profile at the boundary may be constant.

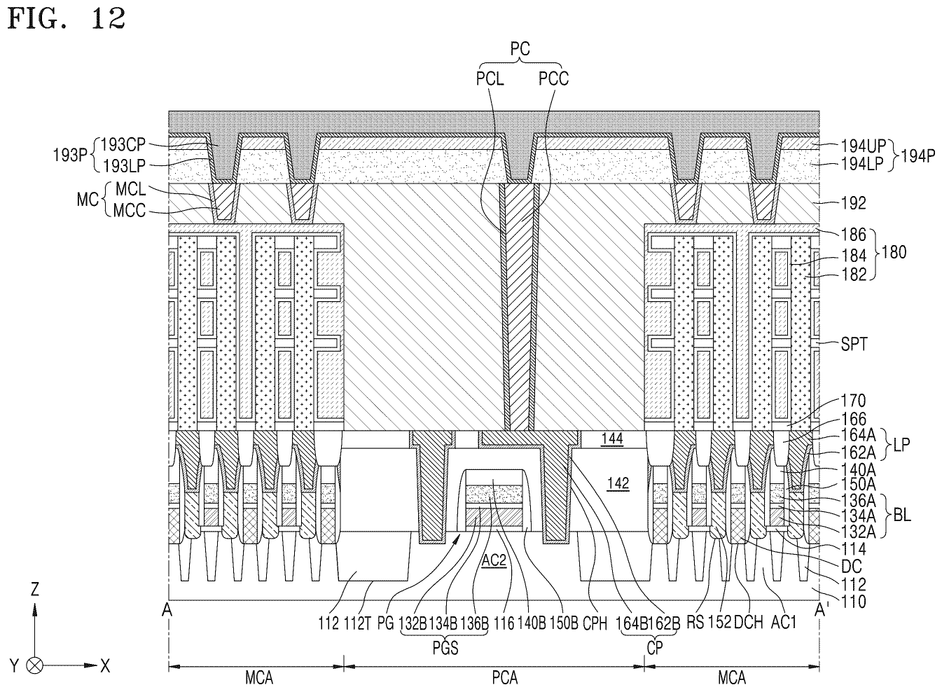

Referring to FIG. 12, a preliminary wiring line barrier film 193LP may be conformally formed to cover inner walls of the plurality of trenches TH and an upper surface of the first preliminary upper interlayer insulating film 194UP. The preliminary wiring line barrier film 193LP may include, for example, titanium (Ti), titanium nitride (TiN), or a combination thereof, but the present inventive concept is not limited thereto.

Next, a preliminary wiring line conductive layer 193CP may be formed to fill the plurality of trenches TH and cover the preliminary wiring line barrier film 193LP. The preliminary wiring line conductive layer 193CP may include, for example, tungsten (W), copper (Cu), aluminum (Al), cobalt (Co), molybdenum (Mo), ruthenium (Ru), titanium (Ti), tantalum (Ta), titanium nitride (TiN), tantalum nitride (TaN), or any combination thereof. For example, the preliminary wiring line conductive layer 193CP may include a copper (Cu) film.

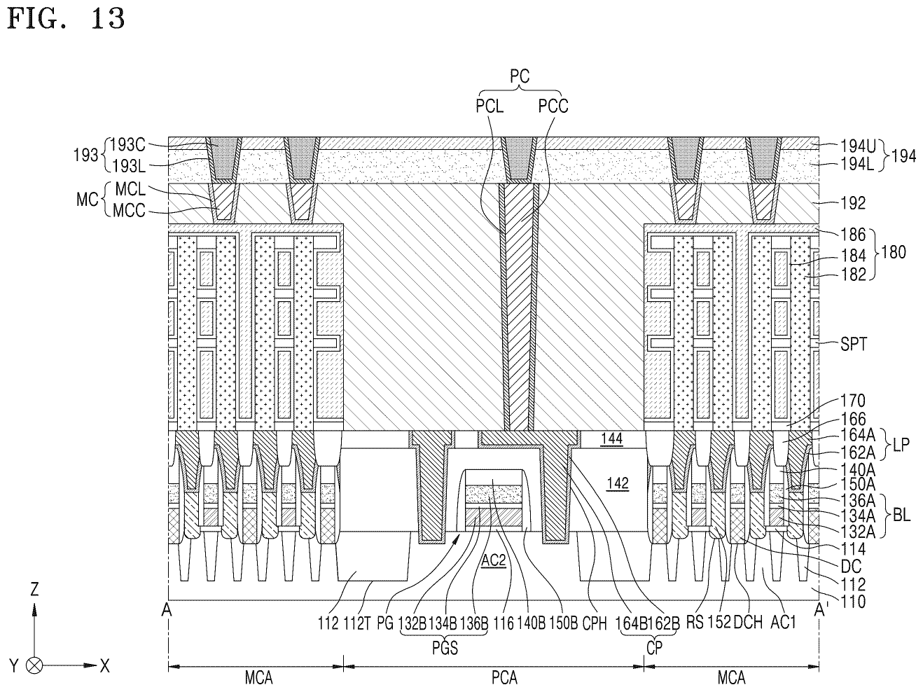

Referring to FIG. 13, the plurality of wiring lines 193 may be formed by removing a portion of the preliminary wiring line conductive layer 193CP, a portion of the preliminary wiring line barrier film 193LP, and a portion of the first preliminary upper interlayer insulating film 194UP. Upper surfaces of the plurality of wiring lines 193 and the first upper interlayer insulating film 194U may be planarized through a planarization process. The planarization process may be, for example, a CMP process. For example, after the planarization process, the upper surfaces of the plurality of wiring lines 193 and the upper surface of the first upper interlayer insulating film 194U may be coplanar.

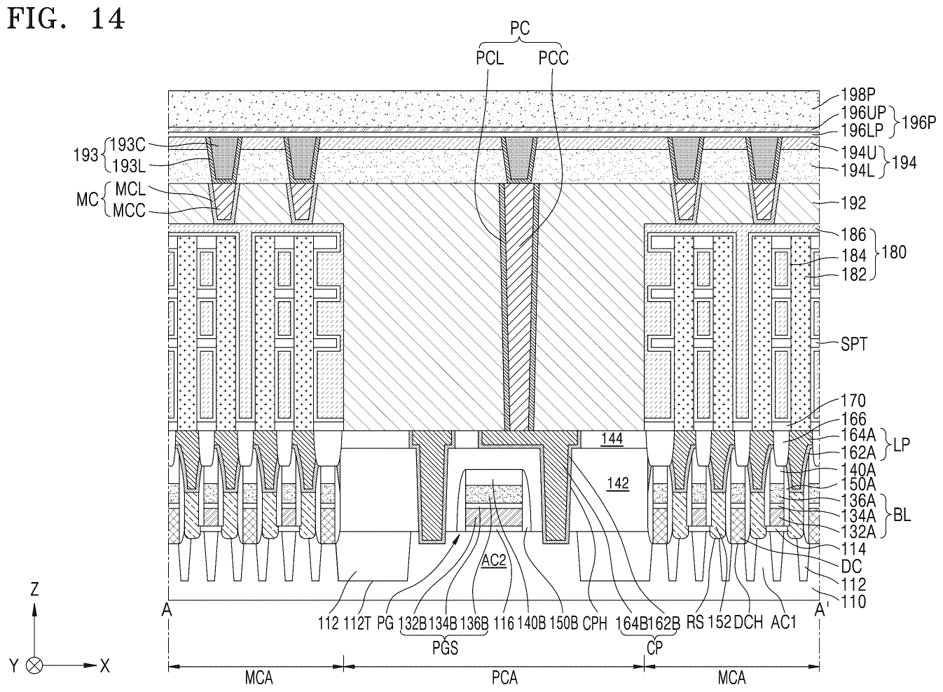

Referring to FIG. 14, a preliminary interlayer capping layer 196P and a second preliminary interlayer insulating film 198P may be formed on the plurality of wiring lines 193 and the first interlayer insulating film 194. The preliminary interlayer capping layer 196P may include a preliminary lower capping layer 196LP and a preliminary upper capping layer 196UP. The preliminary lower capping layer 196LP, the preliminary upper capping layer 196UP, and the second preliminary interlayer insulating film 198P may be sequentially stacked. In an embodiment of the present inventive concept, the preliminary upper capping layer 196UP may include silicon nitride (Si₃N₄), and the preliminary lower capping layer 196LP may include silicon carbonitride (SiCN). In an embodiment of the present inventive concept, the second preliminary interlayer insulating film 198P may include, for example, TEOS, PE-TEOS, LD-TEOS, or any combination thereof.

Because the first lower interlayer insulating film 194L and the first upper interlayer insulating film 194U include the same low dielectric material, sidewalls of the plurality of wiring lines 193 may be coplanar in a region adjacent to a boundary where the first lower interlayer insulating film 194L contacts the first upper interlayer insulating film 194U. Because the first lower interlayer insulating film 194L and the first upper interlayer insulating film 194U include the same low dielectric material, voids may not be generated in the wiring lines 193 during a forming operation of the wiring lines 193.

Referring again to FIG. 3, next, a plurality of metal contact holes that penetrate the preliminary interlayer capping layer 196P and the second preliminary interlayer insulating film 198P may be formed. The plurality of metal contact holes may be formed through an etching process.

Next, an upper contact barrier layer 195L that conformally covers inner walls of the plurality of metal contact holes may be formed. The upper contact barrier layer 195L may include, for example, titanium (Ti), titanium nitride (TiN), or any combination thereof, but the present inventive concept is not limited thereto.

Next, an upper contact conductive layer 195C may be formed to fill the plurality of metal contact holes and cover the upper contact barrier layer 195L, and a plurality of upper contacts 195 may be formed by polishing an upper part of the upper contact barrier layer 195L and an upper part of the upper contact conductive layer 195C.

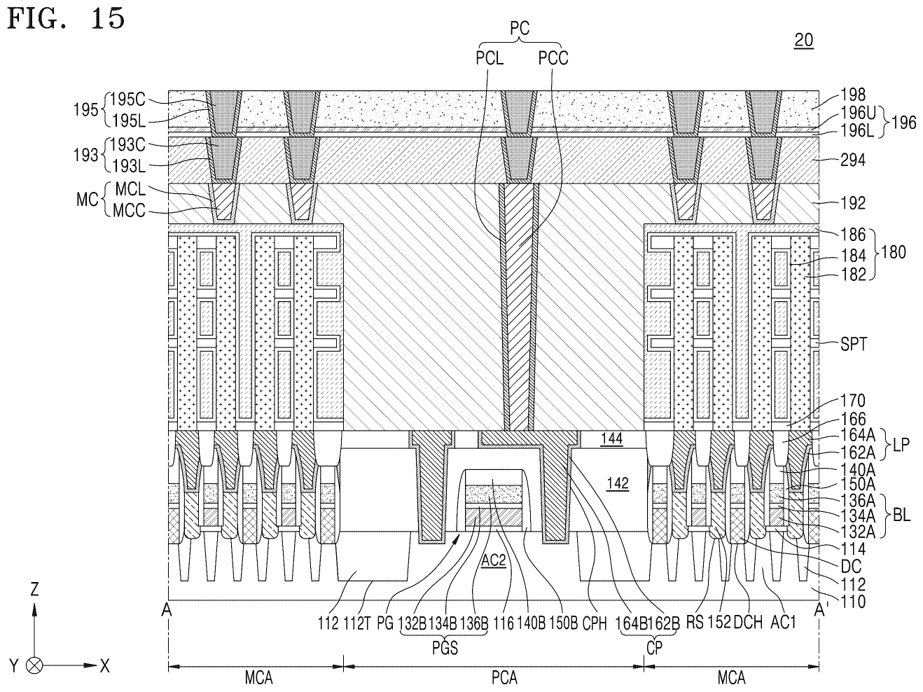

FIG. 15 is a cross-sectional view taken along line A-A′ of FIG. 2 of semiconductor devices 20 according to an embodiment of the present inventive concept.

Referring to FIG. 15, the semiconductor device 20 according to the present inventive concept may include a first interlayer insulating film 294 including a single layer. The semiconductor device 20 of FIG. 15 is substantially the same as the semiconductor device 10 of FIG. 3 except that the semiconductor device 20 of FIG. 15 includes the first interlayer insulating film 294 including a single layer instead of the first upper interlayer insulating film 194U and the first lower interlayer insulating film 194L included in the semiconductor device 10 of FIG. 3, and thus, descriptions given with reference to FIG. 3 are omitted.

In an embodiment of the present inventive concept, the first interlayer insulating film 294 may include a low dielectric material including a benzene ring. For example, the first interlayer insulating film 294 may include a material represented by Chemical Formula 1 below.

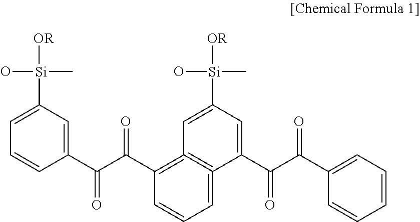

In Chemical Formula 1, R represents an alkyl group, and O—Si— represents Chemical Formula 1 being repeatedly linked to Chemical Formula 1 through SiO bond.

In an embodiment of the present inventive concept, the first interlayer insulating film 294 may include a material having a dielectric constant lower than that of the lower insulating film 192. For example, the first interlayer insulating film 294 may include a material having a dielectric constant lower than that of TEOS, PE-TEOS, LD-TEOS, or any combination thereof.

The first interlayer insulating film 294 includes a low dielectric material including a benzene ring, therefore outgassing of impurities (e.g., H₂O, H⁺) generated in the interlayer insulating film (e.g., including TEOS) during a manufacturing process of a conventional semiconductor device may be prevented. If outgassing of impurities occurs in the interlayer insulating film, a defect in an upper contact may occur and, as a result, the reliability of the semiconductor device may be reduced. The first interlayer insulating film 294 of the semiconductor device 20 of the present inventive concept includes a material represented by Chemical Formula 1, and because the material does not generate impurities, the outgassing phenomenon may be prevented. Because the outgassing phenomenon of the first interlayer insulating film 294 is prevented, formation of a defect in the upper contact 195 may be prevented and productivity and reliability of the semiconductor device 10 may be enhanced.

While the present inventive concept has been particularly shown and described with reference to embodiments thereof, it will be understood that various changes in form and details may be made therein without departing from the spirit and scope of the present inventive as defined by the appended claims.

What is claimed is:

1. A semiconductor device comprising:
a substrate including a memory cell region and a peripheral circuit region, the memory cell region having a first active region and the peripheral circuit region having a second active region;
a capacitor structure including a lower electrode connected to the first active region in the memory cell region, an upper electrode surrounding the lower electrode in the memory cell region, and a capacitor dielectric film disposed between the lower electrode and the upper electrode;
a lower insulating film disposed on the substrate in the memory cell region and the peripheral circuit region, and covering the capacitor structure in the memory cell region;
a first interlayer insulating film including a first lower interlayer insulating film and a first upper interlayer insulating film sequentially stacked on the lower insulating film; and
a wiring line disposed in the first interlayer insulating film and electrically connected to the capacitor structure,
wherein the first upper interlayer insulating film includes a first material including a benzene ring.

2. The semiconductor device of claim 1, wherein the first material is represented by Chemical Formula 1 below: 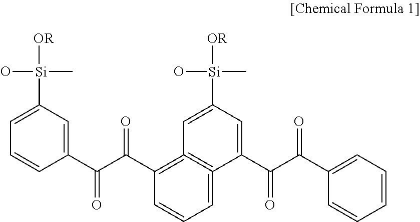
in Chemical Formula 1, R represents an alkyl group, and O—Si— represents Chemical Formula 1 being repeatedly linked to Chemical Formula 1 through SiO bond.

3. The semiconductor device of claim 1, wherein the lower insulating film includes a material having a dielectric constant greater than a dielectric constant of the first material.

4. The semiconductor device of claim 1, wherein the first lower interlayer insulating film includes a second material having a dielectric constant different from a dielectric constant of the first material.

5. The semiconductor device of claim 1, wherein the first lower interlayer insulating film includes a low dielectric material of a same type as the first material.

6. The semiconductor device of claim 1, wherein the first lower interlayer insulating film and the first material include a same material.

7. The semiconductor device of claim 1, further comprising:
an interlayer capping layer including a lower capping layer covering the first interlayer insulating film and an upper capping layer covering the lower capping layer;
a second interlayer insulating film covering the interlayer capping layer; and
an upper contact electrically connected to the wiring line through the second interlayer insulating film and the interlayer capping layer.

8. The semiconductor device of claim 7, wherein
the lower capping layer includes silicon carbonitride, and
the upper capping layer includes silicon nitride.

9. The semiconductor device of claim 7, wherein the second interlayer insulating film includes a material having a dielectric constant greater than a dielectric constant of the first material.

10. The semiconductor device of claim 1, wherein sidewalls of the wiring line are coplanar in a region adjacent to a boundary where the first lower interlayer insulating film and the first upper interlayer insulating film are in contact with each other.

11. The semiconductor device of claim 1, wherein a vertical thickness of the first upper interlayer insulating film is smaller than a vertical thickness of the first lower interlayer insulating film.

12. A method of manufacturing a semiconductor device, the method comprising:
providing a substrate including a memory cell region and a peripheral circuit region, the memory cell region having a first active region and the peripheral circuit region having a second active region;
forming a capacitor structure connected to the first active region in the memory cell region;
forming a lower insulating film covering the substrate and the capacitor structure;
forming a plurality of cell contacts penetrating the lower insulating film in the memory cell region and forming peripheral circuit contacts penetrating the lower insulating film in the peripheral circuit region;
forming a first interlayer insulating film including a first lower interlayer insulating film and a first upper interlayer insulating film sequentially stacked on the lower insulating film; and
forming a wiring line disposed in the first interlayer insulating film and electrically connected to the capacitor structure,
wherein the first upper interlayer insulating film includes a first material including a benzene ring.

13. The method of claim 12, wherein the first material is represented by Chemical Formula 1 below: 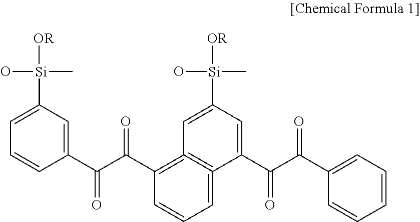
in Chemical Formula 1, R represents an alkyl group, and O—Si— represents Chemical Formula 1 being repeatedly linked to Chemical Formula 1 through SiO bond.

14. The method of claim 12, wherein the forming of the lower insulating film includes forming the lower insulating film using a material having a dielectric constant greater than a dielectric constant of the first material.

15. The method of claim 12, wherein
the forming of the wiring line includes:
forming a trench by etching the first interlayer insulating film;
forming a preliminary wiring line covering the trench and the first interlayer insulating film; and
removing a portion of the preliminary wiring line and a portion of the first upper interlayer insulating film.

16. The method of claim 12, wherein
the forming of the first interlayer insulating film includes forming the first lower interlayer insulating film with a second material having a dielectric constant different from a dielectric constant of the first material.

17. The method of claim 12, wherein the forming of the first interlayer insulating film includes forming the first lower interlayer insulating film with a same material as the first material.

18. The method of claim 12, further comprising:
forming an interlayer capping layer including a lower capping layer covering the first interlayer insulating film and an upper capping layer covering the lower capping layer;
forming a second interlayer insulating film covering the interlayer capping layer; and
forming an upper contact that penetrates through the second interlayer insulating layer and the interlayer capping layer and is electrically connected to the wiring line.

19. The method of claim 12, wherein
the forming of the wiring line includes forming sidewalls of the wiring line to be coplanar in a region adjacent to a boundary where the first lower interlayer insulating film and the first upper interlayer insulating film are in contact with each other.

20. A semiconductor device comprising:
a substrate including a memory cell region and a peripheral circuit region, the memory cell region having a first active region and the peripheral circuit region having a second active region;
a capacitor structure including a lower electrode connected to the first active region in the memory cell region, an upper electrode surrounding the lower electrode in the memory cell region, and a capacitor dielectric film disposed between the lower electrode and the upper electrode;
a lower insulating film disposed on the substrate in the memory cell region and the peripheral circuit region, and covering the capacitor structure in the memory cell region;
a first interlayer insulating film disposed on the lower insulating film and including a first upper interlayer insulating film including a first material including a benzene ring and a first lower interlayer insulating film including a low dielectric material of a same type as the first material; and
a wiring line disposed in the first interlayer insulating film and electrically connected to the capacitor structure, and including sidewalls that are coplanar in a region adjacent to a boundary where the first lower interlayer insulating film and the first upper interlayer insulating film are in contact with each other,
wherein the first upper interlayer insulating film is represented by following Chemical Formula 1: 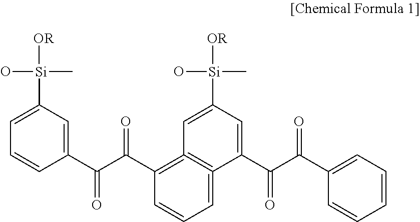
in Chemical Formula 1, R represents an alkyl group, and O—Si— represents Chemical Formula 1 being repeatedly linked to Chemical Formula 1 through SiO bond.
